(19) United States
(12) Patent Application Publication
(10) Pub. No.: US 2024/0426906 A1
(43) Pub. Date: Dec. 26, 2024

(54) GENERATING A TEST PROGRAM

(71) Applicant: Teradyne, Inc., North Reading, MA (US)

(72) Inventor: Charles J. Carline, Londonderry, NH (US)

(21) Appl. No.: 18/211,685

(22) Filed: Jun. 20, 2023

(51) Int. Cl. G01R 31/317; G01R 31/3183; G01R 31/319

(52) U.S. Cl. CPC G01R 31/31704; G01R 31/31708; G01R 31/3172; G01R 31/31725; G01R 31/3183; G01R 31/31924

(57) ABSTRACT

An example method includes the following operations: receiving information about tests performed on a device, where the tests are associated with one or more parameters; performing an optimization process that includes varying the one or more parameters to optimize one or more criteria associated with the tests, where the optimization process includes an artificial intelligence process or a machine learning process; and outputting information that is based on which of the one or more parameters optimizes the one or more criteria.

### TECHNICAL FIELD

This specification describes example implementations of systems and processes for generating a test program.

### BACKGROUND

A test system is configured to test the operation of a device. A device tested by the test system is referred to as a device under test (DUT). The test system may include test instruments and/or a control system that executes test programs to send test signals, such as analog or digital signals and/or data, to the DUT for testing. The DUT replies with response signals. The test system expects the response signals to contain certain values and/or to have a certain timing, for example. If the response signals have the appropriate values and/or timing, the DUT passes testing. If the response signals do not have those values and/or timing, then the DUT may fail testing.

### SUMMARY

An example method includes the following operations: receiving information about tests performed on a device, where the tests are associated with one or more parameters; performing an optimization process that includes varying the one or more parameters to optimize one or more criteria associated with the tests, where the optimization process includes an artificial intelligence process or a machine learning process; and outputting information that is based on which of the one or more parameters optimizes the one or more criteria. The method may include one or more of the following features, either alone or in combination.

The one or more parameters may include one or more of a voltage level of a signal to test the device, a current level of the signal to test the device, a timing of the signal to test the device, a time it takes for the signal to test the device to settle, a pass/fail test result for the device, a sample rate for sampling a pin on the device during testing, or a number of samples sampled on the pin.

The tests may produce results by testing the device using a first test platform that are not wholly correlated to results produced by testing the device using a second test platform. The first test platform may be different from the second test platform.

The one or more criteria may include one or more of repeatability of test results, a time it takes to test the device, a level of correlation between the tests performed on the first test platform and the tests performed on the second test platform, compliance with requirements, or safety for the device.

The artificial intelligence process or machine learning process may include a cost function. The cost function may be configured to optimize the one or more criteria based on variations of the one or more parameters. The cost function may include a non-linear function to optimize the one or more criteria. The cost function may include a linear function to optimize the one or more criteria based on weights associated with the one or more criteria. The cost function may have linear and non-linear components.

The artificial intelligence process or machine learning process may include a genetic algorithm. The genetic algorithm may include a fitness function. The fitness function may be linear or non-linear.

The information may include a report identifying at least one of (i) which of the one or more parameters optimizes the one or more criteria, or (ii) how the one or more criteria are optimized. The report may identify one or more of the tests have not been optimized. The information may include a test program that includes one or more of the tests that have been optimized.

The operations may include: generating a report containing information about tests that produce test results produced by testing the device using a first test platform that are not wholly correlated to test results produced by testing the device using a second test platform; and outputting the report. The report may identify which of the tests produce results on the first test platform are not wholly correlated to test results produced by testing the device using the second test platform.

The optimization process may include a supervised learning process. The artificial intelligence process or machine learning process may include a neural network. The neural network may include a cost function that optimizes the one or more criteria based on variations of the one or more parameters.

The operations may include testing a device on a test platform using a test program comprised of tests having the one or more criteria optimized based on the one or more parameters.

Example one or more non-transitory machine-readable storage media may store instructions that are executable by one or more processing devices to perform operations of the foregoing method, with or without one or more of the foregoing features, either alone or in combination.

An example system may include memory storing instructions that are executable; and one or more processing devices to execute the instructions to perform operations of the foregoing method, with or without of the foregoing features, either alone or in combination.

Any two or more of the features described in this specification, including in this summary section, may be combined to form implementations not specifically described in this specification.

At least part of the devices, systems, techniques, and processes described in this specification may be implemented or controlled by executing, on one or more processing devices, instructions that are stored on one or more non-transitory machine-readable storage media. Examples of non-transitory machine-readable storage media include read-only memory, an optical disk drive, memory disk drive, and random access memory. At least part of the devices, systems, techniques, and processes described in this specification may be implemented or controlled using a computing system comprised of one or more processing devices and memory storing instructions that are executable by the one or more processing devices to perform various control operations. The devices, systems, techniques, and processes described in this specification may be configured, for example, through design, construction, composition, arrangement, placement, programming, operation, activation, deactivation, and/or control.

The details of one or more implementations are set forth in the accompanying drawings and the following description. Other features and advantages will be apparent from the description and drawings, and from the claims.

### DESCRIPTION OF THE DRAWINGS

FIG. 1 is a flowchart showing example operations included in an example process for generating a test program.

FIG. 2 is table showing an example line of an example report generated by the process of FIG. 1.

FIG. 3 is a block diagram showing components of an example test system configured to execute an example test program generated by the process of FIG. 1.

Like reference numerals in different figures indicate like elements.

### DETAILED DESCRIPTION

Test programs are developed to operate on different test systems, also referred to as “test platforms”. Examples of test programs may include computer programs that include one or more test routines. An example test routine includes executable code that is part of the test program and that performs a specific test or tests on a DUT.

When testing the same DUT on different test systems, the same test program ideally would or should provide the same test results. However, this may not be the case in some instances. In an example, a test program run on a first test system to test a DUT produces a first set of test results, which are considered the benchmark test results; for example, they are the test results that should be obtained when testing that DUT on all test systems. The test program may be run on a second test system, such as a newer model test system, to test the same DUT. On the second test system, the test program produces a second set of test results. In this example, the second set of test results is not wholly correlated to the first set of test results, meaning that there are differences between the first set of test results and the second set of test results.

Described herein are example implementations of systems and processes for generating a test program that is optimized based on one or more criteria. For example, the test system may produce benchmark test results when testing a DUT on a different test system from the one that produced the benchmark test results. In the example of the preceding paragraph, the generated test program would produce the benchmark test results, or test results that have an acceptable variance from the benchmark test results, when testing the DUT on the second test system. “Generating” may include modifying, optimizing, editing, revising, altering, amending, correcting, repairing, adjusting, updating, or in any way changing an existing test program. “Generating” may include creating a new test program by combining two or more test routines or developing new test routines based on requirements to test the DUT.

In some implementations, the example systems and processes use machine learning and/or artificial intelligence (AI) to optimize the one or more criteria, such as a level of correlation between test results obtained from a test program executed on a first test system and test results obtained from the same test program executed on a second test system, which is different from the first test system, when testing the same DUT. The one or more criteria may be optimized by varying one or more parameters used in the test program, such as a voltage level of a signal to test the DUT or a current level of the signal to test the DUT. The test program optimized for the one or more criteria constitutes the generated test program in this example. That test program may be used on the second test system for subsequent testing.

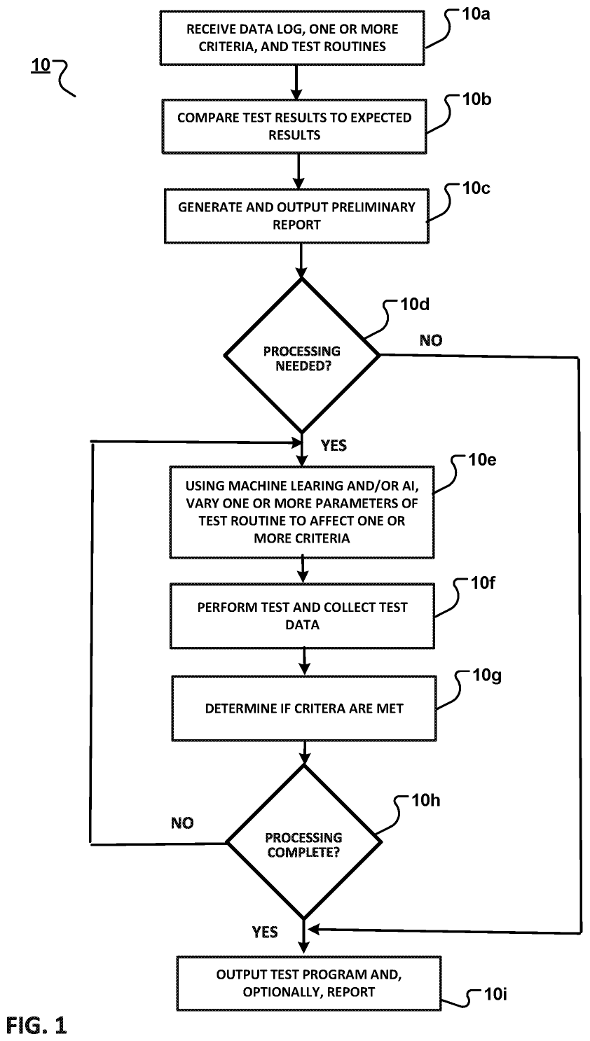

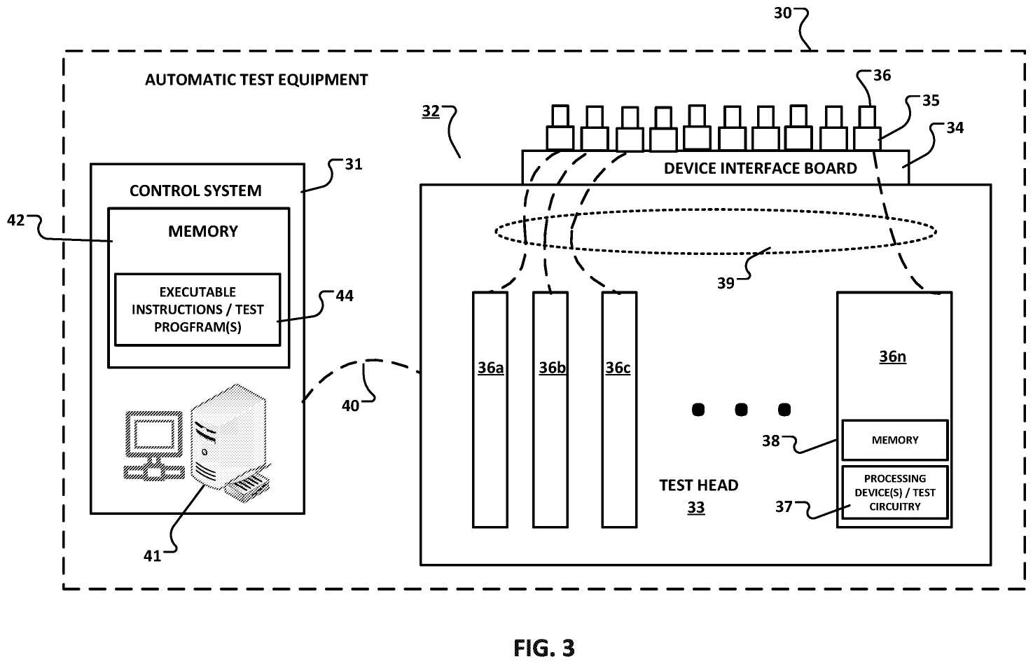

FIG. 1 is a flowchart showing operations included in an example process 10 for generating a test program optimized for one or more criteria. The operations may be performed on a computing system in communication with a test system, such automatic test equipment (ATE) 30 of FIG. 3, or the operations may be performed by a computing system that is part of the ATE, such as control system 31 described below.

Process 10 includes receiving (10a) test routines for performing tests on a DUT. The test routines may be individual software modules or the test routines may be part of a test program containing multiple test routines. The test routines are processed as described herein to generate a test program optimized for one or more criteria.

Process 10 receives (10a) a data log. The data log includes the benchmark test results described above. The benchmark test results may include any test results that can be expected for a DUT. For example, the benchmark test results may include values for a voltage to expect from the DUT in response to a test signal output to the DUT, values for a current to expect from the DUT in response to a test signal output to the DUT, values for timing information indicative of a response of the DUT to a test signal, and/or other types of test results. The data log also includes test results obtained from the received test routines run on a test system, such as ATE 30 FIG. 3, that is different from the test system that produced the benchmark test results. The test results obtained from the test routines are counterparts, in whole or in part, to the benchmark test results. For example, if the benchmark test results include a voltage to expect from a pin of the DUT in response to a 5 millivolt (mV) test signal output to the DUT, then the test results obtained from the test routines also include a voltage to expect from the same pin of the same DUT in response to the same 5 mV test signal.

Process 10 receives (10a) one or more criteria. The one or more criteria may include, for example, operational features of the received test program that are to be optimized by process 10. Examples of the criteria include, but are not limited to, one or more of: repeatability of test results, a time it takes to test a DUT, a level of correlation between the tests performed on a first (e.g., benchmark) test system and the same tests performed on a second test system on the same DUT, compliance with requirements, or safety for the DUT. In an example, repeatability of test results includes the same test producing the same test results on the same DUT two or more times. In an example, the time it takes to test the DUT includes the amount of time it takes for a test program to test a DUT. In an example, the level of correlation includes the extent to which test results produced by the test program are identical to benchmark test results, where the test results and the benchmark test results are for the same test (e.g., a response to a 5 mV test signal on a particular DUT pin) for the same DUT in some implementations. In an example, compliance with requirements includes whether the test program complies with test requirements, such as limits on time to test the DUT, limits on power needed to test the DUT, limits on cost of testing the DUT, and so forth. In an example, safety for the DUT includes the risk of damage to the DUT in response, e.g., to signals that exceed predefined levels, such as current or voltage levels.

In cases where more than one criterion is received, the priority of each criterion may be specified as part of the data received (10a). The priority of the criteria may be specified by weights associated with the criteria. The weights may be selected by a DUT manufacturer. Greater weights may indicate a higher priority given to a criterion, and lesser weights may indicate a lower priority given to a criterion.

Process 10 compares (10b) the test results to the benchmark test results. This comparison identifies which, if any, of the test results are not correlated to the benchmark test results. For example, the comparison identifies differences between the received test results and corresponding benchmark test results. If there are no differences, then the test results are wholly correlated to the benchmark test results. If there are differences, then the test results are not wholly correlated to the benchmark test results. In cases where the test results are not wholly correlated to the benchmark test results, the test results are said to be uncorrelated to the benchmark test results.

Process 10 generates and outputs (10c) a preliminary report indicating whether the test results are wholly correlated to the benchmark test results and, if not, which test routines produced test results that are not correlated to the benchmark test results.

Process 10 determines (10d) whether processing of the test routines is needed. For example, if the test results are wholly correlated to the benchmark test results, then processing may not be needed. On the other hand, if the test results are wholly correlated to the benchmark test results, processing may still be performed to affect (e.g., to optimize) one or more criteria other than level of correlation. The determination (10d) may be based on the received (10a) one or more criteria. For example, if a criterion is received to optimize test time, then processing may still be performed to change the test routines in an attempt to improve test time without affecting the level or correlation or by affecting the level of correlation only with a predefined acceptable limit, which may be programmed into the computing system by a test engineer.

In some implementations, processing may be needed only for test routines that produced test results that are not correlated to the benchmark test results. In these examples, therefore, a subset of the received (10a) test routines may be processed.

If no processing is needed (10d), process 10 may output (10i) a report to that effect and/or a test program. In this particular example, the test program may be the received test program such as amalgamation of the received test routines.

If processing is needed (10d), process 10 uses (10e) machine learning and/or AI to vary one or more parameters of each test routine in order to affect (e.g., to optimize) the test program based for the one or more received (10a) criteria. Examples of the one or more parameters include, but are not limited to, one or more of: a voltage level of a signal to test a DUT, a current level of the signal to test the DUT, a timing of the signal to test the DUT, a time it takes for the signal to test the DUT to settle, a pass/fail test result for the DUT, a sample rate for sampling a pin on the DUT during testing, and/or a number of samples sampled on the pin of the DUT. Parameters other than, or in addition to, these may be varied by the machine learning and/or AI processes.

Examples machine learning processes that may be used include, but are not limited to, a neural network or supervised learning. In some implementations, machine learning processes train a machine learning model (“model”) using training data. The model may be trained by repeatedly exposing the model to examples of inputs and outputs and by adjusting weights of the model to minimize an error of the model's output compared an the expected output. In this example, the inputs include varied values of the one or more parameters, the outputs include the outputs of the model, and the expected outputs include the benchmark test results.

A cost function is a measure of how well the machine learning model performs that quantifies the difference between expected and actual outputs. The cost function is to be minimized by varying the model's parameters during training The cost function may be configured to optimize the test program for the one or more criteria (e.g., level of correlation). For example, the cost function may vary one or more of the parameters—in some examples all of the parameters or a subset thereof—which are then used inputs to train the machine learning model. In some implementations, the cost function may take into account customer objectives for the criteria, such as predefined values associated with the criteria. These predefined values may weight the criteria based on their importance to the customer. The cost function may therefore vary the parameters, which are used to train the machine learning model, based on these predefined values.

The cost function may be a linear cost function in which the variations of the parameters affect the optimization cost function linearly. The cost function may be a non-linear cost function. The cost function may have any appropriate form.

Examples AI processes that may be used include a genetic algorithm. An example genetic algorithm implements a model of computation by using arrays of bits or characters referred to as “genes” to represent “chromosomes”. Each string represents a potential solution to an optimization problem, such as optimizing one or more of the received (10a) criteria. The genetic algorithm manipulates the most promising chromosomes to search for improved solutions to the optimization problem. In some implementations, the genetic algorithm processes each chromosome of a population using a fitness function, and processes the chromosome using mutation and/or crossover operations to produce a new generation of the population. The fitness function is calculated iteratively until one or more stopping criteria are met. In an example, each chromosome may contain test parameters such as those described herein that are varied in order to optimize the one or more received (10a) criteria.

In a case where multiple criteria are optimized, the fitness function takes into consideration the multiple criteria and those criteria based on customer objectives. In one example of a linear fitness function, the genetic algorithm assigns weights to those criteria and defines coefficients of the linear fitness function as the weights when performing the optimization. For example, the genetic algorithm may be used to optimize correlation, repeatability, and test time. There may be a trade-off between these three criteria, meaning that it may not be possible to optimize all three concurrently; accordingly, the optimum result may be based on customer objectives for the criteria, such as predefined values representing levels of correlation, repeatability, and test time. In the linear fitness function example, the weights may be based on these predefined values representing customer objectives.

In a particular example, input to the fitness function includes candidate test conditions, such as 10 possible DC voltage levels for signals to the DUT which are iterated on by the fitness function to find the “best” one of these 10 voltage levels settings that optimize the received (10a) one or more criteria.

The fitness function may be a linear fitness function in which the variations of the parameters affect the optimization linearly. The fitness function may be a non-linear fitness function. The fitness function may have any appropriate form.

An explanation of how a genetic algorithm works and may be used in process 10 is described in the following document, which is incorporated herein by reference: Vijini Mallawaarachchi, “Introduction to Genetic Algorithms—Including Example Code”, Towards Data Science (Jul. 7, 2017) (https://towardsdatascience.com/introduction-to-genetic-algorithms-including-example-code-e396e98d8bf3 (accessed Jun. 6, 2023)). Although a genetic algorithm is described, any appropriate AI optimization process may be used with, or in place of, the genetic algorithm.

In this example, the result of operation 10e is a test program, which includes multiple test routines, that have been modified (e.g., optimized) based on the received (10a) criteria. Process 10 performs (10f) testing on the same DUT used to produce the benchmark test data using the test program of operation 10e and a test system (like that described with respect to FIG. 3) that is the same test system used to produce the originally received (10a) test results. Process 10 collects (10f) test data obtained from the execution of the test program on that test system and analyzes that test data to determine (10g) if the received (10a) criteria are met, e.g., by determining if one or more predefined values for the received (10a) criteria are met. If the received (10a) criteria are not met, processing is determined (10h) not to be complete. In that case, the collected test data is processed in accordance with operations 10e through 10g in order to further modify (e.g., optimize) the test program. These operations may be repeated one or more times until the received (10a) one or more criteria are met by the test program. When process 10 determines that the one or more criteria have been met (10h), processing proceeds to operation 10i.

Process 10 outputs (10i) the test program of operation 10e and, optionally, a report identifying performance of the generated test program, or routines contained therein, relative to the originally-received (10a) test routines. The report may also identify changes in the generated test program made by the machine learning/AI (10e) relative to the routines received (10a) originally, such as which of the parameters were varies and the values of those parameters that have been varied. Process 10 may then use the test program to test subsequent DUTs on a test system like that of FIG. 3, for example.

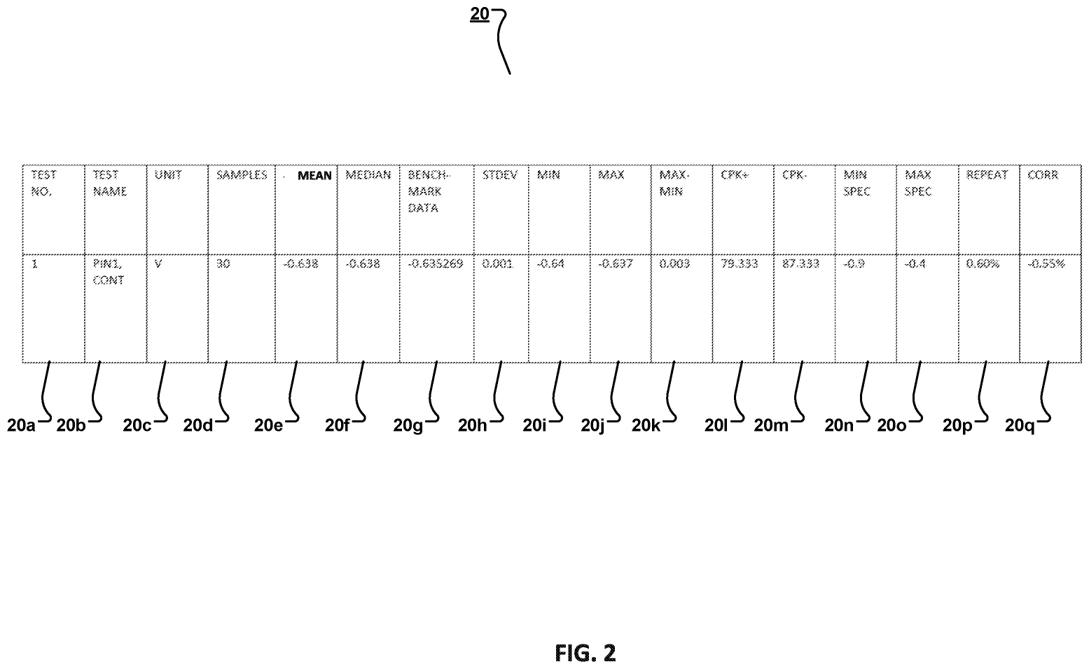

FIG. 2 shows an example of part 20 of a report (e.g., a single line of the report) that may be generated using process 10 for testing performed on a non-benchmark test system. In this example, report 20 identifies the test number 20a, the test name 20b, and the unit 20c of the test signal, here “V” for volts. The report includes the number of samples 20d taken from a DUT pin, which correspond to instances of test data. The report includes mean 20e, which is the mean of the 30 samples. The report includes a median 20f determined for the number of samples. The report includes benchmark test data 20g, which is data obtained from a benchmark test system running a version of the test program used to produce the test data of FIG. 2 for test 20a. Benchmark test data 20g may also be obtained from device simulation data provide by a DUT manufacturer. The report includes STDEV 20h, or standard deviation, minimum 20i, maximum 20j, and max-min (maximum-minimum) 20k. These are all determined from the number of samples 20d and represent a standard deviation from the mean, minimum value, maximum value, and a difference between the maximum and minimum values, respectively, of the number of samples. The report includes CPK+ 20l and CPK-20m. These are statistical calculations. A low value for CPK+ or CPK−, such as below one, indicates that, statistically, one should expect DUT failures to happen intermittently. These values represent combinations of how wide the distribution of the 30 samples 20d is and how close they are to the min spec and the max spec. The min spec 20n and the max spec 200 represent lower and upper bounds, respectively, of test samples 20d. The report also includes repeat 20p, which is an indication of a variation across all of the 30 samples relative to the width of the specification limits. Repeat 20p is calculated by dividing the “max-min” result by “max spec-min spec. The report also includes corr 20q. Corr 20q indicates a correlation of the test data for samples 20d to corresponding benchmark test data 20g. In the example of FIG. 2, the −0.55% value of corr 20q means that the test data for samples 20d was −0.55% different from the corresponding benchmark test data 20g. Acceptance criteria for corr 20q varies from DUT manufacturer to DUT manufacturer. Sometimes 5% or even 10% corr is acceptable. Other DUT manufacturer will demand corr to be <1% for some critical tests.

FIG. 3 is a block diagram showing components of example ATE 30 that includes a testing device/apparatus (referred to also as a “tester”) 32 and a control system 31.

ATE 30 includes a test head 33 and a device interface board (DIB) 34 connected physically and electrically to test head 33. In this example, DIB 34 includes a circuit board that includes mechanical and electrical interfaces at sites 35. One or more DUTs 36 connect to each of those sites for testing by the ATE. DIB 34 may include, among other things, connectors, conductive traces, conductive layers, and circuitry for routing signals between test instruments in the test head 33, DUTs connected to DIB sites, and other circuitry in the ATE. Power, including voltage, may be run via one or more layers in the DIB to DUTs connected to the DIB.

Test head 33 includes multiple test instruments 36a to 36n (where n>3), each of which may be configured, as appropriate, to implement testing and/or other functions. Although only four test instruments are shown, ATE 30 may include any appropriate number of test instruments, including one or more residing outside of test head 33. The test instruments may be hardware devices that may include one or more processing devices and/or other circuitry 37. The test instruments may be configured—for example, programmed—to output test signals to test DUTs held on the DIB. The test signals to test the DUTs may be or include commands, instructions, data, parameters, variables, test patterns, and/or any other information designed to elicit response(s) from the DUT. Each test instrument may have a configuration like that of test instrument 36n, which includes one or more processing devices and/or test circuitry 37, and memory 38 storing instructions that are executable by the one or more processing devices to generate test signals to send to the DUTs, to communicate with control system 31, and to analyze responses to the test signals. Test circuitry may also perform these functions.

In some implementations, test signals to test a DUT may be generated by test program(s) received by ATE 30 from an external system. In an example, a test program may be or include a set of instructions that are executed or interpreted by ATE 30 to produce test signals that the ATE uses to test the DUT. Examples of test programs that may be used are generated using process 10 of FIG. 1.

Test channels 39 are configured between the test head and the DIB to enable communication between the DUTs and the test instruments.

Control system 31 is configured—e.g., programmed—to communicate with test instruments 36a to 36n to direct and/or to control testing of the DUTs. In some implementations, this communication 40 may be over a computer network or via a direct connection such as a computer bus or an optical medium. In some implementations, the computer network may be or include a local area network (LAN) or a wide area network (WAN). The control system may be or include a computing system comprised of one or more processing devices 41 (e.g., microprocessor(s)) and memory 42 for storing instructions to execute to control operation of the ATE and/or testing, and/or one or more test programs to execute and/or to send to the test instruments for execution. Control system 31 may be configured to provide test programs and/or test signals to test instruments 36a to 36n in the test head, which the test instrument(s) use to test the DUT. Control system 31 may also be configured to receive DUT response signals (e.g., measurement data) from the test instrument(s) and to determine whether the corresponding DUT has passed or failed testing.

In some implementations, the control functionality is centralized in processing device(s) 41. In some implementations, all or part of the functionality attributed to control system 31 may also or instead be implemented on a test instrument and/or all or part of the functionality attributed to one or more test instruments may also or instead be implemented on control system 31. For example, the control system may be distributed across processing device(s) 41 and one or more of test instruments 36a to 36n.

All or part of the test systems and processes described in this specification and their various modifications may be configured or controlled at least in part by one or more computers such as control system 31 using one or more computer programs tangibly embodied in one or more information carriers, such as in one or more non-transitory machine-readable storage media. A computer program can be written in any form of programming language, including compiled or interpreted languages, and it can be deployed in any form, including as a stand-alone program or as a module, part, subroutine, or other unit suitable for use in a computing environment. A computer program can be deployed to be executed on one computer or on multiple computers at one site or distributed across multiple sites and interconnected by a network.

Actions associated with configuring or controlling the test system and processes described herein can be performed by one or more programmable processors executing one or more computer programs to control or to perform all or some of the operations described herein. All or part of the test systems and processes can be configured or controlled by special purpose logic circuitry, such as, an FPGA (field programmable gate array) and/or an ASIC (application-specific integrated circuit) or embedded microprocessor(s) localized to the instrument hardware.

Processors suitable for the execution of a computer program include, by way of example, both general and special purpose microprocessors, and any one or more processors of any kind of digital computer. Generally, a processor will receive instructions and data from a read-only storage area or a random access storage area or both. Elements of a computer include one or more processors for executing instructions and one or more storage area devices for storing instructions and data. Generally, a computer will also include, or be operatively coupled to receive data from, or transfer data to, or both, one or more machine-readable storage media, such as mass storage devices for storing data, such as magnetic, magneto-optical disks, or optical disks. Non-transitory machine-readable storage media suitable for embodying computer program instructions and data include all forms of non-volatile storage area, including by way of example, semiconductor storage area devices, such as EPROM (erasable programmable read-only memory), EEPROM (electrically erasable programmable read-only memory), and flash storage area devices; magnetic disks, such as internal hard disks or removable disks; magneto-optical disks; and CD-ROM (compact disc read-only memory) and DVD-ROM (digital versatile disc read-only memory).

In the description and claims provided herein, the adjectives “first”, “second”, “third”, and the like do not designate priority or order. Instead, these adjectives are used solely to differentiate the nouns that they modify.

Any mechanical or electrical connection herein may include a direct physical connection or an indirect connection that includes intervening components.

Elements of different implementations described may be combined to form other implementations not specifically set forth previously. Elements may be left out of the systems described previously without adversely affecting their operation or the operation of the system in general. Furthermore, various separate elements may be combined into one or more individual elements to perform the functions described in this specification.

Other implementations not specifically described in this specification are also within the scope of the following claims.

What is claimed is:

1. A method comprising:
receiving information about tests performed on a device, wherein the tests are associated with one or more parameters;
performing an optimization process that includes varying the one or more parameters to optimize one or more criteria associated with the tests, wherein the optimization process comprises an artificial intelligence process or a machine learning process; and
outputting information that is based on which of the one or more parameters optimizes the one or more criteria.

2. The method of claim 1, wherein the one or more parameters comprises one or more of: a voltage level of a signal to test the device, a current level of the signal to test the device, a timing of the signal to test the device, a time it takes for the signal to test the device to settle, a pass/fail test result for the device, a sample rate for sampling a pin on the device during testing, or a number of samples sampled on the pin.

3. The method of claim 1, wherein the tests produce results by testing the device using a first test platform that are not wholly correlated to results produced by testing the device using a second test platform, the first test platform being different from the second test platform.

4. The method of claim 3, wherein the one or more criteria comprise one or more of: repeatability of test results, a time it takes to test the device, a level of correlation between the tests performed on the first test platform and the tests performed on the second test platform, compliance with requirements, or safety for the device.

5. The method of claim 1, wherein the artificial intelligence process or machine learning process comprises a cost function, the cost function to optimize the one or more criteria based on variations of the one or more parameters.

6. The method of claim 5, wherein the cost function comprises a non-linear function to optimize the one or more criteria.

7. The method of claim 5, wherein the cost function comprises a linear function to optimize the one or more criteria based on weights associated with the one or more criteria.

8. The method of claim 1, wherein the artificial intelligence process or machine learning process comprises a genetic algorithm.

9. The method of claim 9, wherein the genetic algorithm comprises a fitness function that is either linear or non-linear.

10. The method of claim 1, wherein the information comprises a report identifying at least one of (i) which of the one or more parameters optimizes the one or more criteria, or (ii) how the one or more criteria are optimized.

11. The method of claim 10, wherein the report identifies one or more of the tests have not been optimized.

12. The method of claim 1, wherein the information comprises a test program comprising one or more of the tests that have been optimized.

13. The method of claim 1, further comprising:
generating a report containing information about tests that produce test results by testing the device using a first test platform that are not wholly correlated to test results produced by testing the device using a second test platform; and
outputting the report.

14. The method of claim 13, wherein the report identifies which of the tests produce results on the first test platform are not wholly correlated to test results produced by testing the device using the second test platform.

15. The method of claim 1, wherein the optimization process comprises a supervised learning process.

16. The method of claim 1, further comprising:
testing a device on a test platform using a test program comprised of tests having the one or more criteria optimized based on the one or more parameters.

17. The method of claim 1, wherein the artificial intelligence process or machine learning process comprises a neural network, the neural network comprising a cost function that optimizes the one or more criteria based on variations of the one or more parameters.

18. One or more non-transitory machine-readable storage media storing instructions that are executable by one or more processing devices to perform operations comprising:
receiving information about tests performed on a device, wherein the tests are associated with one or more parameters;
performing an optimization process that includes varying the one or more parameters to optimize one or more criteria associated with the tests, wherein the optimization process comprises an artificial intelligence process or a machine learning process; and
outputting information that is based on which of the one or more parameters optimizes the one or more criteria.

19. The one or more non-transitory machine-readable storage media of claim 18, wherein the one or more parameters comprises one or more of: a voltage level of a signal to test the device, a current level of the signal to test the device, a timing of the signal to test the device, a time it takes for the signal to test the device to settle, a pass/fail test result for the device, a sample rate for sampling a pin on the device during testing, or a number of samples sampled on the pin.

20. The one or more non-transitory machine-readable storage media of claim 18, wherein the tests produce results by testing the device using a first test platform that are not wholly correlated to results produced by testing the device using a second test platform, the first test platform being different from the second test platform.

21. The one or more non-transitory machine-readable storage media of claim 20, wherein the one or more criteria comprise one or more of: repeatability of test results, a time it takes to test the device, a level of correlation between the tests performed on the first test platform and the tests performed on the second test platform, compliance with requirements, or safety for the device.

22. The one or more non-transitory machine-readable storage media of claim 18, wherein the artificial intelligence process or machine learning process comprises a cost function, the cost function to optimize the one or more criteria based on variations of the one or more parameters.

23. The one or more non-transitory machine-readable storage media of claim 22, wherein the cost function comprises a non-linear function to optimize the one or more criteria.

24. The one or more non-transitory machine-readable storage media of claim 22, wherein the cost function comprises a linear function to optimize the one or more criteria based on weights associated with the one or more criteria.

25. The one or more non-transitory machine-readable storage media of claim 18, wherein the artificial intelligence process or machine learning process comprises a genetic algorithm.

26. The one or more non-transitory machine-readable storage media of claim 25, wherein the genetic algorithm comprises a fitness function that is either linear or non-linear.

27. The one or more non-transitory machine-readable storage media of claim 18, wherein the information comprises a report identifying at least one of (i) which of the one or more parameters optimizes the one or more criteria, or (ii) how the one or more criteria are optimized.

28. The one or more non-transitory machine-readable storage media of claim 27, wherein the report identifies one or more of the tests have not been optimized.

29. The one or more non-transitory machine-readable storage media of claim 18, wherein the information comprises a test program comprising one or more of the tests that have been optimized.

30. The one or more non-transitory machine-readable storage media of claim 18, wherein the operations further comprise:
generating a report containing information about tests that produce test results by testing the device using a first test platform that are not wholly correlated to test results produced by testing the device using a second test platform; and
outputting the report.

31. The one or more non-transitory machine-readable storage media of claim 3-30, wherein the report identifies which of the tests produce results on the first test platform are not wholly correlated to test results produced by testing the device using the second test platform.

32. The one or more non-transitory machine-readable storage media of claim 18, wherein the optimization process comprises a supervised learning process.

33. The one or more non-transitory machine-readable storage media of claim 18, wherein the operations further comprise:
testing a device on a test platform using a test program comprised of tests having the one or more criteria optimized based on the one or more parameters.

34. The one or more non-transitory machine-readable storage media of claim 18, wherein the artificial intelligence process or machine learning process comprises a neural network, the neural network comprising a cost function that optimizes the one or more criteria based on variations of the one or more parameters.

35. A system comprising:
memory storing instructions that are executable; and
one or more processing devices to execute the instructions to perform operations comprising:
receiving information about tests performed on a device, wherein the tests are associated with one or more parameters;
performing an optimization process that includes varying the one or more parameters to optimize one or more criteria associated with the tests, wherein the optimization process comprises an artificial intelligence process or a machine learning process; and
outputting information that is based on which of the one or more parameters optimizes the one or more criteria.
